(19) United States
(12) Patent Application Publication
(10) Pub. No.: US 2021/0388495 A1
(43) Pub. Date: Dec. 16, 2021

(54) ASYMMETRIC EXHAUST PUMPING PLATE DESIGN FOR A SEMICONDUCTOR PROCESSING CHAMBER

(71) Applicant: Applied Materials, Inc., Santa Clara, CA (US)

(72) Inventors: Akshay Gunaji, Karnataka (IN); Mayur Govind Kulkarni, Bangalore (IN)

(73) Assignee: Applied Materials, Inc., Santa Clara, CA (US)

(21) Appl. No.: 16/902,911

(22) Filed: Jun. 16, 2020

(51) Int. Cl. C23C 16/44; H01L 21/67; H01L 21/033; H01L 21/02; H01J 37/32; C23C 16/26; C23C 16/505

(52) U.S. Cl. CPC C23C 16/4412; H01L 21/67017; H01L 21/0332; H01L 21/02115; H01L 21/02274; H01J 2237/3323; H01J 37/32834; C23C 16/26; C23C 16/505; H01J 2237/3321; H01J 37/32899

(57) ABSTRACT

Exemplary semiconductor processing chambers may include a chamber body including sidewalls and a base. The chambers may include a substrate support extending through the base of the chamber body. The substrate support may include a support platen configured to support a semiconductor substrate. The substrate support may include a shaft coupled with the support platen. The chambers may include a foreline conduit offset from a center of the base for exhausting a gas from the chamber body, and an exhaust volume coupled to the foreline conduit. The chambers may include a pumping plate comprising a central aperture through which the shaft extends, and further comprising exit apertures for directing at least a portion of the gas from the chamber body to the exhaust volume. The exit apertures may be disposed at locations opposite the foreline conduit so as to reduce nonuniformity in gas flow.

### TECHNICAL FIELD

The present technology relates to components and apparatuses for semiconductor manufacturing. More specifically, the present technology relates to processing chamber components and other semiconductor processing equipment.

### BACKGROUND

Integrated circuits are made possible by processes which produce intricately patterned material layers on surfaces of a substrate (e.g., a semiconductor wafer). Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### SUMMARY

Exemplary semiconductor processing chambers may include a chamber body including sidewalls and a base. The chambers may include a substrate support extending through the base of the chamber body. The substrate support may include a support platen configured to support a semiconductor substrate. The substrate support may include a shaft coupled with the support platen. The chambers may include a foreline conduit offset from a center of the base for exhausting a gas from the chamber body, and an exhaust volume coupled to the foreline conduit. The chambers may include a pumping plate comprising a central aperture through which the shaft extends, and further comprising exit apertures for directing at least a portion of the gas from the chamber body to the exhaust volume. The exit apertures may be disposed at locations opposite the foreline conduit so as to reduce nonuniformity in gas flow.

In some embodiments, the pumping plate may be circular, and the one or more exit apertures may include a plurality of exit apertures disposed along an arcuate path opposite the foreline conduit and defined along a first radius with respect to a center of the pumping plate. The foreline conduit on the base may be located along the first radius. The exit apertures may be symmetrically disposed with respect to a first axis of the pumping plate extending along a diameter of the pumping plate. The exit apertures may be asymmetrically disposed along a second axis of the pumping plate, and the second axis may be perpendicular to the first axis. The arcuate path may have an arc angle between about 30 degrees and 345 degrees. The first axis may be parallel to the exhaust volume. A gap between an edge of the central aperture and an outer diameter of the shaft may be less than or about 1 cm, and the gap may be configured to direct another portion of the gas from the chamber body to the exhaust volume. The gap may be less than or about 1 mm. The exhaust volume may be formed between the base and the pumping plate. The base may include a first extension extending toward the pumping plate. The pumping plate may include a second extension extending toward the base. The first extension and the second extension may be configured to at least partially overlap vertically so as to restrict gas flow from the chamber body to the foreline conduit via the central aperture. A minimum vertical gap between the base and the pumping plate may be less than or about 2 mm. The minimum vertical gap between the base and the pumping plate may be about 1.6 mm.

Some embodiments of the present technology may encompass pumping plates for exhausting gases from a chamber body of a semiconductor processing system. The pumping plate may include a central aperture for receiving a shaft extending through the chamber body. The central aperture may be sized so as to minimize a gap between an edge of the central aperture and an outer diameter of the shaft to be less than or about 1 cm. The central aperture may be configured to provide a first pathway for directing a gas from the chamber body toward an exhaust volume. The pumping plates may define a plurality of exit apertures for providing a plurality of second pathways for directing the gas from the chamber body toward the exhaust volume. The exit apertures may be disposed along the pumping plate at one or more locations configured to be opposite an outlet of the chamber body when the pumping plate is positioned within the chamber body.

In some embodiments the pumping plate may be circular, and the exit apertures may be disposed along an arcuate path opposite the outlet of the chamber body and defined along a radius with respect to a center of the pumping plate. The exit apertures may be symmetrically disposed with respect to a first axis of the pumping plate extending along a diameter of the pumping plate. The exit apertures may be asymmetrically disposed along a second axis of the pumping plate, and the second axis may be perpendicular to the first axis.

Some embodiments of the present technology may encompass methods of semiconductor processing. The methods may include flowing a carbon-containing precursor into a processing chamber. The processing chamber may include a faceplate and a substrate support on which a substrate is disposed. The substrate support may extend through a base of the processing chamber. The substrate support may include a support platen on which the substrate is disposed, and a shaft coupled with the support plate. The methods may include generating a plasma of the carbon-containing precursor within the processing chamber. The methods may include depositing a carbon-containing material on the substrate. The methods may include exhausting a gas from a chamber body of the processing chamber via a pumping plate through which the shaft extends. The pumping plate may include one or more exit apertures for directing at least a portion of the gas from the chamber body to an exhaust volume coupled to a foreline conduit on the base. The one or more exit apertures may be disposed along the pumping plate at one or more locations opposite the foreline conduit so as to reduce a nonuniformity in gas flow within the exhaust volume.

In some embodiments the pumping plate may be circular. The one or more exit apertures may be a plurality of exit apertures disposed along an arcuate path opposite the foreline conduit and defined along a first radius with respect to a center of the pumping plate. The exit apertures may be symmetrically disposed with respect to a first axis of the pumping plate extending along a diameter of the pumping plate. The exit apertures may be asymmetrically disposed along a second axis of the pumping plate. The second axis may be perpendicular to the first axis. The arcuate path may have an arc angle between about 30 degrees and 345 degrees.

Such technology may provide numerous benefits over conventional systems and techniques. For example, embodiments of the present technology may improve gas flow uniformity across a substrate. Additionally, the components may allow modification to accommodate any number of chambers or processes. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIGS. 4A-4B show overhead views of example embodiments of a pumping plate.

FIG. 5 is a close-up cross-section view of the system in FIG. 3, showing the shaft extending through the pumping plate and the base via the central aperture.

FIG. 6 shows operations of an exemplary method of semiconductor processing according to some embodiments of the present technology

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity. Many processing chambers include asymmetric exhausting systems, where gases are not exhausted from the processing chambers uniformly from all sides of the chamber, creating a skew in the outflow of gases. For example, a single-exhaust PECVD chamber may include a foreline conduit (for exhausting gases from the chamber body) that is disposed along one side of the chamber, causing a skew in gas flow toward that side. This skew may create nonuniformity of gas flow throughout the chamber, which may produce nonuniformity of gas flow across a substrate. This nonuniformity of gas flow may create film uniformity differences across the substrate for materials produced or removed. That is, the resulting substrate may be characterized by varied thickness of depositions or varied film properties across the surface of the substrate. Such variance may be undesirable and may ultimately lead to semiconductor failures.

The present technology overcomes these challenges to provide better planar uniformity in the flow of gases as they are exhausted from the processing chamber. The described processing chambers incorporate flow pathways that optimally account for or reduce skews in gas flow within the processing chamber caused by asymmetric exhaust systems where exhaust is pulled from a radial position about the chamber. Specifically, flow pathways are created to increase exhaust flow along regions of the processing chamber offset from the foreline conduit. Accordingly, the present technology may produce improved film deposition characterized by improved uniformity in thickness and material property across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

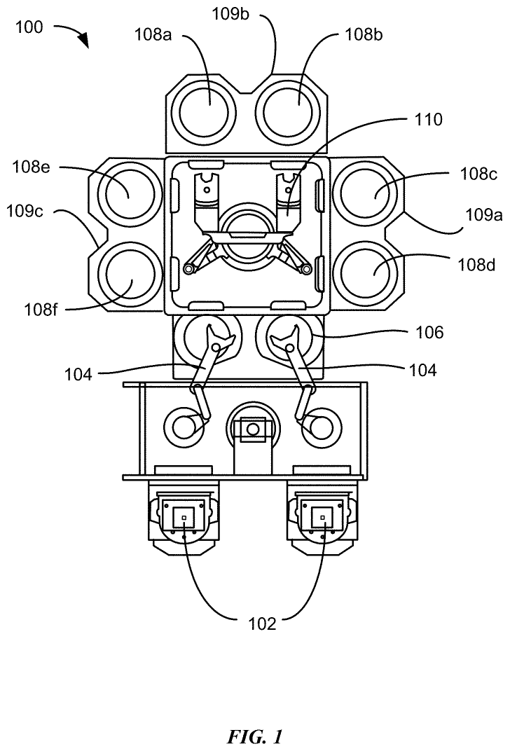

FIG. 1 shows a top plan view of one embodiment of a processing system 100 of deposition, etching, annealing, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

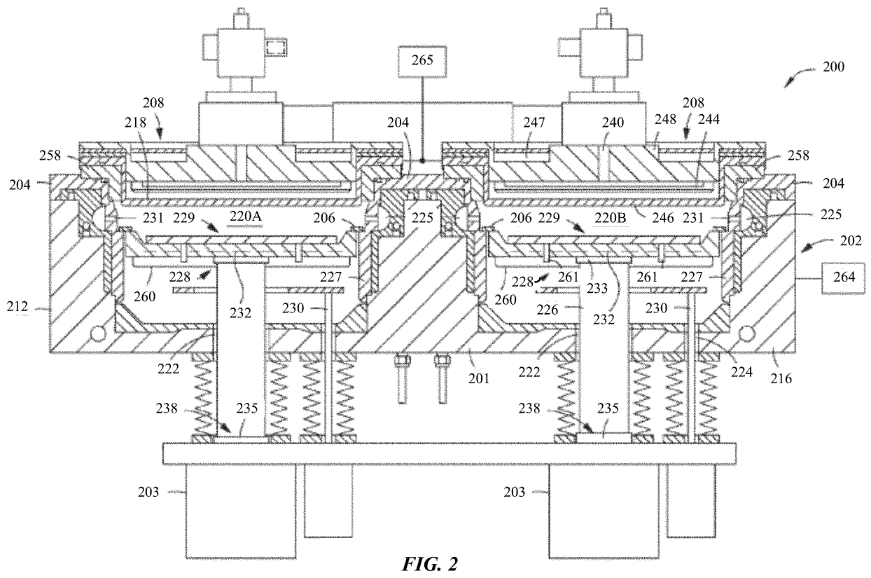

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or showerheads or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device. The pedestal 228 may also contain an electrostatic or vacuum chucking capability.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring or edge ring 206 may be disposed on the periphery of the pedestal 228 that engages the pedestal 228.

An optional cooling channel 247 may be formed in the gasbox 248 of the gas distribution system 208 to cool the gasbox 248 or maintain a constant temperature environment during operation. A heat transfer fluid, such as water, ethylene glycol, a gas, or the mixture thereof the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

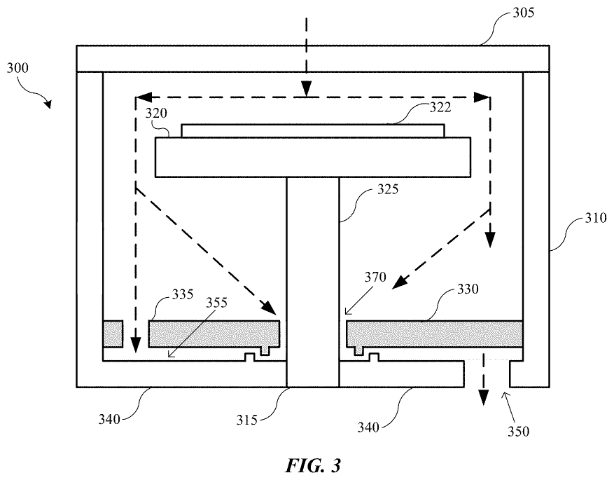

FIG. 3 shows a schematic partial cross-sectional view of an exemplary processing system 300 according to some embodiments of the present technology. The processing system 300 includes an asymmetric exhaust system. The illustrated example is a single-exhaust system (e.g., a single-exhaust PECVD chamber) with a single foreline conduit 350. FIG. 3 may illustrate further details relating to components in system 200, such as for pedestal 228. System 300 is understood to include any feature or aspect of system 200 discussed previously in some embodiments, but may add, modify, or omit particular features or aspects of system 200. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system, and may illustrate a view across a center of the faceplate, which may otherwise be of any size, and include any number of apertures. Any aspect of system 300 may also be incorporated with other processing chambers or systems as will be readily understood by the skilled artisan.

System 300 may include a processing chamber including a faceplate 305, through which precursors may be delivered for processing, and which may be coupled with a power source for generating a plasma within the processing region of the chamber. The chamber may also include a chamber body 310, which as illustrated may include sidewalls and a base 340. A pedestal or substrate support 315 may extend through the base 340 of the chamber as previously discussed. The substrate support may include a support platen 320, which may support semiconductor substrate 322. The support platen 320 may be coupled with a shaft 325, which may extend through the base 340 of the chamber. In some embodiments, a heating element may be mounted onto the interior of the base 340, for use in heating the interior of the chamber body 310 from the bottom. Alternatively, the base 340 itself may be a heating element.

As explained above, semiconductor processing involves flowing a plurality of gases over the semiconductor substrate 322 and throughout the chamber body 310. These gases need to be exhausted from the chamber body 310 during different stages of the process. In some embodiments, the exhaust mechanism of system 300 incorporates a pumping plate 330, which may be a plate including one or more exit apertures (e.g., the exit aperture 335 illustrated in FIG. 3) configured to control the flow of gases out of the chamber body 310, as will be explained in further detail below. The exit apertures of the pumping plate 330 may be configured to provide a pathway to conduct gases toward an exhaust volume 355. In the example illustrated in FIG. 3, the exhaust volume 355 may be an open channel between the pumping plate and the base 340 of the system 300 that is fluidically coupled to a foreline conduit 350. As described previously, the chamber system may be a tandem chamber system, and both chambers may exhaust separately into a foreline or system exhaust. The exhaust volume of each chamber may be independent and isolated in each chamber to be maintained fluidly separate from the other chamber of the system. In some embodiments, the foreline conduit 350 may be coupled to a vacuum source to aid with the exhausting of gases from the chamber body 310. In some embodiments, the pumping plate 330 may include a central aperture 370, through which the shaft 325 extends. In some embodiments, there may be a gap between edges of the central aperture 370 and the outer diameter of the shaft 325, which may provide an additional path for conducting gases to the foreline conduit 350. The dashed arrows illustrate the flow of gases from a chamber inlet (not shown) at the top of the chamber over and around the substrate 322 and support platen 320, into the exhaust volume 355 via exit apertures (e.g., the exit aperture 335) in the pumping plate 330 and the central aperture 370, and finally out the foreline conduit 350.

As discussed above, processing chambers with asymmetric exhausting systems may tend to cause nonuniform flow within the chamber body as gases are exhausted from the chamber body. For example, in a conventional single-exhaust system, a foreline conduit, which may be coupled to a vacuum source, may be disposed on one side of the chamber body. When gases are exhausted from the chamber body, the gases may flow from a central aperture (e.g., similar to the central aperture 370 in FIG. 3) toward the foreline conduit via an exhaust volume. In such systems, since the foreline conduit is asymmetrically disposed, there tends to be a skew in gas flow toward the foreline conduit, which creates nonuniform flow throughout the chamber as the gases are exhausted. Such nonuniform flow impacts may create film uniformity differences across the substrate, causing the resulting substrate to be characterized by varied thickness of depositions or varied film properties across the surface of the substrate.

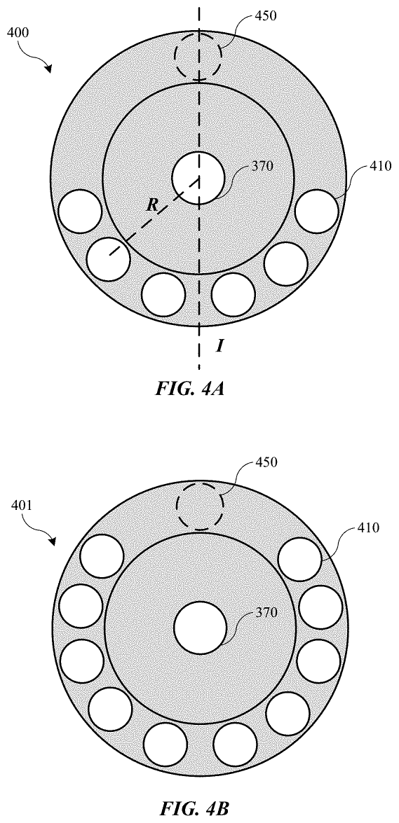

FIGS. 4A-4B show overhead views of example embodiments of a pumping plate 400.

Embodiments of the pumping plate 400 may serve to create additional flow pathways that may reduce or prevent the skew in the exhausting of gases and create more uniform planar flow as gases leave the chamber body via the foreline conduit. Pumping plates may be made from any suitable material (e.g., aluminum, alumina, aluminum nitride). In some embodiments, the pumping plate may include one or more exit apertures for controlling the flow of gases from a chamber body of a semiconductor processing system as described above. Referencing FIG. 4A for example, the pumping plate 400 may include six exit apertures 410 configured to conduct gases from a chamber body (e.g., the chamber body 310 of FIG. 3) to an exhaust volume (e.g., 355 of FIG. 3). The exit apertures 410 may be of any suitable shape (e.g., circular, rectangular, triangular) or size (e.g., 0.5 cm to 1 cm, 1 cm to 2.5 cm, 0.5 to 2.5 cm), and exemplary pumping plates may include any number of apertures in embodiments of the present technology. The pumping plate 400 further includes a central aperture 370 through which a shaft (e.g., the shaft 325 of FIG. 3) may extend. In the illustrated embodiment, the exit apertures 410 are disposed along the pumping plate opposite to where a foreline conduit is expected to be when the pumping plate 400 is assembled within a semiconductor processing system. FIG. 4A illustrates a chamber-outlet outline 450 of where the foreline conduit is expected to be (e.g., as illustrated in FIG. 3, on the base 340 directly under the pumping plate 330). In the example embodiment of FIG. 4A, the exit apertures 410 are disposed along an arcuate path opposite the foreline conduit and defined along a radius R with respect to a center of the pumping plate. In some embodiments, the semiconductor processing system may be configured such that the foreline conduit on the base also falls along the radius R such that a single imaginary circular path can trace the exit apertures and foreline conduit. In some embodiments, the exit apertures may be symmetrically disposed with respect to an axis of the pumping plate (e.g., the axis extending along a diameter of the pumping plate). For example, referencing FIG. 4A, the exit apertures 410 are symmetrically disposed with respect to the axis I (e.g., the three exit apertures 410 on the left of the axis I are mirrored by the three exit apertures 410 on the right of the axis I). In some embodiments, the axis I may run parallel to the exhaust volume.

As a means of countering the above-described skew in gas flow, the exit apertures may be disposed asymmetrically along an axis other than the axis I (e.g., to an axis perpendicular to the axis I). As illustrated in FIG. 4A, this asymmetry favors gas flow through the side of the pumping plate 400 opposite the foreline conduit (illustrated by the outline 450). This may serve to reduce nonuniformity of gas flow within the chamber body, including regions proximate to the support platen and across the substrate. In some embodiments, the axis I may run parallel to the exhaust volume.

FIG. 4B shows another embodiment of the pumping plate. The illustrated pumping plate 401 is similar to the pumping plate 400, except that it includes ten exit apertures 410, again disposed asymmetrically and favoring the side of the pumping plate 401 opposite the foreline conduit (illustrated by the outline 450). As illustrated the apertures 410 are along an arcuate path greater than the apertures 410 of the pumping plate 400. It is noted that the illustrated embodiments are not necessarily to scale. In some embodiments, the arcuate path may be disposed opposite the foreline conduit with an arc angle of 180 degrees or less. In other embodiments, the arcuate path may be disposed opposite the foreline conduit with an arc angle of greater than 180 degrees. In other embodiments, any suitable arc angle between about 30 degrees and 345 degrees may be employed. In some embodiments the pumping plate may be devoid of any apertures along an arcuate path having a midpoint extending across the foreline conduit to limit direct fluid flow to the outlet. Such an arcuate path characterized without apertures may extend less than or about 330 degrees about the pumping plate, less than or about 180 degrees about the pumping plate, less than or about 30 degrees about the pumping plate, or less. In some embodiments, particular pumping plates may be selected based on chamber flows. That is, different chamber flows may require different pumping plates (each having different characteristics like exit aperture sizes, exit aperture locations, central aperture sizes, etc.) from a set of potential pumping plates.

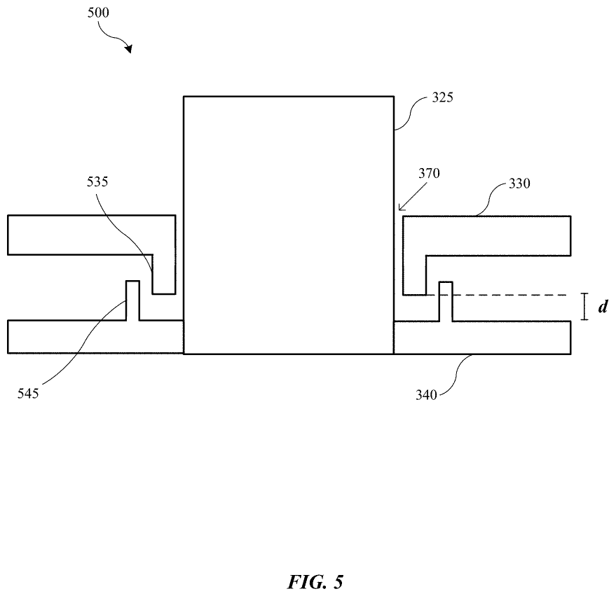

FIG. 5 is a close-up cross-section view of the system in FIG. 3, showing the shaft 325 extending through the pumping plate 330 and the base 340 via the central aperture 370. The central aperture 370 may be of any suitable shape or size. As discussed above, conventional systems may use a central aperture similar to the central aperture 370 as the only or primary pathway for exhausting gases through a foreline conduit via the exhaust volume. Embodiments of the present technology may attempt to reduce the flow of gases through the central aperture 370, for example, so as to increase the effect of the exit apertures (e.g., referencing FIGS. 4A-4B, the exit apertures 410) of the pumping plate 330 and thereby aid with countering the skew in flow as described above. In some embodiments, the gap between edges of the central aperture 370 and the outer diameter of the shaft 325 may be minimized to reduce the flow of gases. For example, the gap may be reduced to less than or about 1 cm, between 1 cm and 1 mm, or less than or about 1 mm. In some embodiments, the pumping plate 330 and the base 340 may include one or more extensions along the exhaust volume 355 so as to reduce gas flow via the central aperture 370. For example, as illustrated in FIG. 5, the base 340 may include a first extension 545 and the pumping plate 330 may include a second extension 535 (e.g., which may circumferentially extend around the shaft 325). In this example, the first extension 545 and the second extension 535 may be configured to at least partially overlap vertically so as to restrict gas flow. Referencing FIG. 5, the extent of the overlap may be characterized by a minimum vertical gap d between the base and the pumping plate (e.g., between the first extension 545 and the pumping plate 330, or between the second extension 535 and the base 340). In some embodiments, a minimum vertical gap between the base and the pumping plate may be less than or about 2 mm. In some embodiments, the first extension 545 and the second extension 535 may have the same or similar vertical height such that they extend approximately the same distance. In some embodiments, the extensions may extend perpendicular to the base 340 or the pumping plate 330, or may alternatively extend at an angle.

In some embodiments, a method of semiconductor processing may include flowing a carbon-containing precursor into a processing chamber, where the processing chamber includes a faceplate and a substrate support on which a substrate is disposed, and where the substrate support extends through a base of the processing chamber. The method may further include generating a plasma of the carbon-containing precursor within the processing chamber. The method may further include depositing a carbon-containing material on the substrate. The method may further include exhausting a gas from a chamber body of the processing chamber via a pumping plate such as the ones described in the present disclosure.

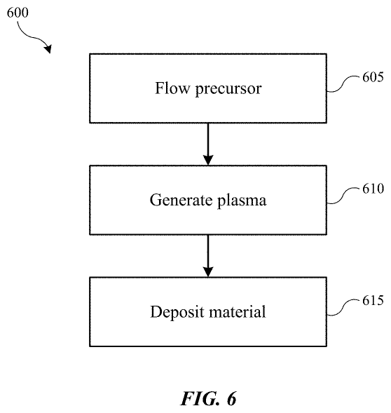

FIG. 6 shows operations of an exemplary method 600 of semiconductor processing according to some embodiments of the present technology. The method may be performed in a variety of processing chambers, including processing system 200 described above, which may include pumping plates and other features according to embodiments of the present technology. Method 600 may include a number of optional operations, which may or may not be specifically associated with some embodiments of methods according to the present technology.

Method 600 may include a processing method that may include operations for forming a hardmask film or other deposition operations. The method may include optional operations prior to initiation of method 600, or the method may include additional operations. For example, method 600 may include operations performed in different orders than illustrated. In some embodiments, method 600 may include flowing one or more precursors into a processing chamber at operation 605. For example, the precursor may be flowed into a chamber, such as included in system 200, and may flow the precursor through one or more of a gasbox, a blocker plate, or a faceplate, prior to delivering the precursor into a processing region of the chamber. In some embodiments the precursor may be or include a carbon-containing precursor.

In some embodiments, a pumping plate may be included in the system near the base, such as about a shaft portion. Any of the other characteristics of pumping plates described previously may also be included, including any aspect of pumping plates 330, 400, and 401, such as the different asymmetric exit apertures. Similarly, features for reducing gas flow through a central aperture of the system may be included, such as the first extension 545 and the second extension 535 and the minimizing of the size of the central aperture. At operation 610, a plasma may be generated of the precursors within the processing region, such as by providing RF power to the faceplate to generate a plasma. Material formed in the plasma, such as a carbon-containing material, may be deposited on the substrate at operation 615.

In some embodiments, testing on the substrate may be performed subsequent processing. Based on an effect on the substrate, characteristics of the pumping plate (e.g., the number of exit apertures, the sizes of exit apertures, the sizes of the central aperture) may be adjusted by switching among different pumping plates. Similarly, features such as extensions may be adjusted. This may provide feed-forward control of processing and selective tuning of processes, which may limit losses from non-uniformity due to chamber effects.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system comprising:
a chamber body comprising sidewalls and a base;
a substrate support extending through the base, wherein the substrate support comprises:
a support platen configured to support a semiconductor substrate, and
a shaft coupled with the support platen;
a foreline conduit on the base configured to exhaust a gas from the chamber body, wherein the foreline conduit is offset from a center of the base;
an exhaust volume coupled to the foreline conduit; and
a pumping plate comprising a central aperture through which the shaft extends, and further comprising one or more exit apertures for directing at least a portion of the gas from the chamber body to the exhaust volume, wherein the one or more exit apertures are disposed along the pumping plate at one or more locations opposite the foreline conduit so as to reduce a nonuniformity in gas flow proximate the support platen.

2. The semiconductor processing system of claim 1, wherein the pumping plate is circular, and wherein the one or more exit apertures comprise a plurality of exit apertures disposed along an arcuate path opposite the foreline conduit and defined along a first radius with respect to a center of the pumping plate.

3. The semiconductor processing system of claim 2, wherein the foreline conduit on the base is located along the first radius.

4. The semiconductor processing system of claim 2, wherein the exit apertures are symmetrically disposed with respect to a first axis of the pumping plate extending along a diameter of the pumping plate.

5. The semiconductor processing system of claim 4, wherein the exit apertures are asymmetrically disposed along a second axis of the pumping plate, wherein the second axis is perpendicular to the first axis.

6. The semiconductor processing system of claim 4, wherein the arcuate path has an arc angle between about 30 degrees and 345 degrees.

7. The semiconductor processing system of claim 4, wherein the first axis is parallel to the exhaust volume.

8. The semiconductor processing system of claim 1, wherein a gap between an edge of the central aperture and an outer diameter of the shaft is less than or about 1 cm, and wherein the gap is configured to direct another portion of the gas from the chamber body to the exhaust volume.

9. The semiconductor processing system of claim 8, wherein the gap is less than or about 1 mm.

10. The semiconductor processing system of claim 8, wherein:
the exhaust volume is formed between the base and the pumping plate,
the base comprises a first extension extending toward the pumping plate, and
the pumping plate comprises a second extension extending toward the base, the first extension and the second extension being configured to at least partially overlap vertically so as to restrict gas flow from the chamber body to the foreline conduit via the central aperture.

11. The semiconductor processing system of claim 10, wherein a minimum vertical gap between the base and the pumping plate is less than or about 2 mm.

12. The semiconductor processing system of claim 11, wherein the minimum vertical gap between the base and the pumping plate is about 1.6 mm.

13. A pumping plate for exhausting gases from a chamber body of a semiconductor processing system, wherein the pumping plate comprises:
a central aperture for receiving a shaft extending through the chamber body, wherein the central aperture is sized so as to minimize a gap between an edge of the central aperture and an outer diameter of the shaft is less than or about 1 cm, wherein the central aperture is configured to provide a first pathway for directing a gas from the chamber body toward an exhaust volume; and
a plurality of exit apertures for providing a plurality of second pathways for directing the gas from the chamber body toward the exhaust volume, wherein the exit apertures are disposed along the pumping plate at one or more locations configured to be opposite an outlet of the chamber body when the pumping plate is positioned within the chamber body.

14. The pumping plate of claim 13, wherein the pumping plate is circular, and wherein the exit apertures are disposed along an arcuate path opposite the outlet of the chamber body and defined along a radius with respect to a center of the pumping plate.

15. The pumping plate of claim 14, wherein the exit apertures are symmetrically disposed with respect to a first axis of the pumping plate extending along a diameter of the pumping plate.

16. The pumping plate of claim 15, wherein the exit apertures are asymmetrically disposed along a second axis of the pumping plate, wherein the second axis is perpendicular to the first axis.

17. A method of semiconductor processing comprising:
flowing a carbon-containing precursor into a processing chamber, wherein the processing chamber comprises a faceplate and a substrate support on which a substrate is disposed, wherein the substrate support extends through a base of the processing chamber, wherein the substrate support comprises:
a support platen on which the substrate is disposed, and
a shaft coupled with the support platen,
generating a plasma of the carbon-containing precursor within the processing chamber;
depositing a carbon-containing material on the substrate; and
exhausting a gas from a chamber body of the processing chamber via a pumping plate through which the shaft extends, wherein the pumping plate comprises one or more exit apertures for directing at least a portion of the gas from the chamber body to an exhaust volume coupled to a foreline conduit on the base, wherein the one or more exit apertures are disposed along the pumping plate at one or more locations opposite the foreline conduit so as to reduce a nonuniformity in gas flow within the exhaust volume.

18. The method of semiconductor processing of claim 17, wherein:
the pumping plate is circular, and wherein the one or more exit apertures comprise a plurality of exit apertures disposed along an arcuate path opposite the foreline conduit and defined along a first radius with respect to a center of the pumping plate; and
the exit apertures are symmetrically disposed with respect to a first axis of the pumping plate extending along a diameter of the pumping plate.

19. The method of semiconductor processing of claim 18, wherein the exit apertures are asymmetrically disposed along a second axis of the pumping plate, wherein the second axis is perpendicular to the first axis.

20. The method of semiconductor processing of claim 18, wherein the arcuate path has an arc angle between about 30 degrees and 345 degrees.
